(19) United States
(12) Patent Application Publication
(10) Pub. No.: US 2026/0363000 A1
(43) Pub. Date: Nov. 12, 2026

(54) SEMICONDUCTOR DEVICES AND RELATED METHODS

(71) Applicant: SEMICONDUCTOR COMPONENTS INDUSTRIES, LLC, Scottsdale, AZ (US)

(72) Inventor: Joseph JOHNSON, Hopewell Junction, NY (US)

(73) Assignee: SEMICONDUCTOR COMPONENTS INDUSTRIES, LLC, Scottsdale, AZ (US)

(21) Appl. No.: 19/202,673

(22) Filed: May 8, 2025

(51) Int. Cl. H10P 50/00; H10D 64/23; H10W 72/50; H10W 72/90; H10W 74/01; H10W 74/10; H10W 74/43; H10W 74/47

(52) U.S. Cl. CPC H10P 50/691; H10W 74/01; H10W 74/137; H10W 74/43; H10W 74/47; H10W 74/473; H10D 64/252; H10W 72/541; H10W 72/90; H10W 72/923; H10W 72/932; H10W 72/9415; H10W 72/942; H10W 72/952

(57) ABSTRACT

Implementations of a semiconductor device may include a semiconductor substrate including a thickness; a gate pad coupled to the semiconductor substrate; and an electrically insulative material in the thickness of the semiconductor substrate directly coupled to the gate pad.

### BACKGROUND

### 1. Technical Field

Aspects of this document relate generally to semiconductor devices. More specific implementations involve power semiconductor devices.

### 2. Background

Various semiconductor devices have been devised that allow for transfer and handling of electricity. The semiconductor devices are formed on semiconductor substrates. Various semiconductor package designs have been devised to allow semiconductor devices to be operatively coupled with a circuit board or motherboard during operation.

### SUMMARY

Implementations of a semiconductor device may include a semiconductor substrate including a thickness; a gate pad coupled to the semiconductor substrate; and an electrically insulative material in the thickness of the semiconductor substrate directly coupled to the gate pad.

Implementations of a semiconductor device may include one, all, or any of the following:

The electrically insulative material may extend entirely across the thickness of the semiconductor substrate.

The semiconductor substrate and the electrically insulative material may be covered with a backmetal material.

The device may include one or more gate runners electrically coupled with the gate pad.

The device may include a bond wire directly coupled to the gate pad.

The perimeter of the electrically insulative material may be within a perimeter of the gate pad.

The thickness of the semiconductor substrate may be less than 50 microns thick.

The electrically insulative material may be a mold compound.

The electrically insulative material may be a passivation material.

Implementations of a method of making a semiconductor device may include providing a semiconductor substrate including a thickness; forming a gate pad on a surface of the semiconductor substrate; and thinning the thickness of the semiconductor substrate to a final thickness. The method may also include, adjacent to the gate pad, etching the semiconductor substrate through the final thickness to form a gate pad opening; and applying a mold compound into the gate pad opening.

Implementations of a method of making a semiconductor device may include one, all, or any of the following:

The method may include forming a patterned layer on the semiconductor substrate prior to etching the semiconductor substrate.

The method may include removing the mold compound from a largest planar surface of the semiconductor substrate after applying.

The method may include forming a backmetal layer over a largest planar surface of the semiconductor substrate and over the mold compound.

The method may include wirebonding a bond wire to the gate pad.

Implementations of a method of making a semiconductor device may include providing a semiconductor substrate including a thickness; forming a patterned layer on a first largest planar surface of the semiconductor substrate; and etching the semiconductor substrate into the thickness to form a gate pad opening. The method may include forming a layer of passivation material on the first largest planar surface and into the gate pad opening; removing the layer of passivation material from the first largest planar surface; forming a gate pad over the gate pad opening; and thinning the thickness of the semiconductor substrate to a final thickness.

Implementations of a method of making a semiconductor device may include one, all, or any of the following:

The method may include removing the patterned layer on the semiconductor substrate after etching the semiconductor substrate.

The method may include forming a backmetal layer over a second largest planar surface of the semiconductor substrate.

The method may include wirebonding a bond wire to the gate pad.

The gate pad opening may extend only partially into the final thickness.

The perimeter of the gate pad opening may be within a perimeter of the gate pad.

The foregoing and other aspects, features, and advantages will be apparent to those artisans of ordinary skill in the art from the DESCRIPTION and DRAWINGS, and from the CLAIMS.

### BRIEF DESCRIPTION OF THE DRAWINGS

Implementations will hereinafter be described in conjunction with the appended drawings, where like designations denote like elements, and:

FIG. 1 is a cross sectional view of an implementation of a semiconductor device with a bond wire bonded to a gate pad;

FIG. 2 is a top view of the implementation of a semiconductor device of FIG. 1 with gate runners;

FIG. 3 a top view of four semiconductor die implementations prior to singulation;

FIG. 4 is a bottom view of the four semiconductor die implementations prior to singulation;

FIG. 5 is a cross sectional view of an implementation of a semiconductor device following formation of a gate pad;

FIG. 6 is a cross sectional view of the semiconductor device of FIG. 5 in a flipped orientation;

FIG. 7 is a cross sectional view of the semiconductor device of FIG. 6 during a thinning operation;

FIG. 8 is a cross sectional view of the semiconductor device of FIG. 7 following a patterning operation;

FIG. 9 is a cross sectional view of the semiconductor device of FIG. 8 during an etching operation;

FIG. 10 is a cross sectional view of the semiconductor device of FIG. 9 following a molding operation;

FIG. 11 is a cross sectional view of the semiconductor device of FIG. 10 following a grinding/mold compound removal operation;

FIG. 12 is a cross sectional view of a semiconductor die like that of FIG. 11 after formation of a backmetal layer thereon and after a wirebonding operation;

FIG. 13 is a cross sectional view of an implementation of a semiconductor device;

FIG. 14 is a cross sectional view of the semiconductor device of FIG. 13 following a patterning operation and during an etching operation;

FIG. 15 is a cross sectional view of the semiconductor device of FIG. 14 following deposition of a layer of passivation material thereon;

FIG. 16 is a cross sectional view of the semiconductor device of FIG. 15 following removal of passivation material therefrom;

FIG. 17 is a cross sectional view of the semiconductor device of FIG. 16 following formation of a gate pad thereon;

FIG. 18 is a cross sectional view of the semiconductor device of FIG. 17 during a thinning operation;

FIG. 19 is a cross sectional view of the semiconductor device of FIG. 18 after the thinning operation;

FIG. 20 is a cross sectional view of the semiconductor device of FIG. 19 following formation of a backmetal layer thereon; and

FIG. 21 is a cross sectional view of a semiconductor die of FIG. 20 in a flipped orientation after a wirebonding operation.

### DESCRIPTION

This disclosure, its aspects and implementations, are not limited to the specific components, assembly procedures or method elements disclosed herein. Many additional components, assembly procedures and/or method elements known in the art consistent with the intended semiconductor devices will become apparent for use with particular implementations from this disclosure. Accordingly, for example, although particular implementations are disclosed, such implementations and implementing components may comprise any shape, size, style, type, model, version, measurement, concentration, material, quantity, method element, step, and/or the like as is known in the art for such semiconductor devices, and implementing components and methods, consistent with the intended operation and methods.

The various semiconductor devices disclosed herein are thinned, meaning that the total thickness of the device is smaller than an original thickness of the substrate used during at least part of the fabrication process of the devices. The original thickness of the semiconductor substrates that is used during the fabrication process often depends on the diameter or largest dimension of the substrates. Larger diameter/dimensioned semiconductor substrates have a correspondingly larger thickness to ensure the substrate remains sufficiently stiff to not warp excessively during processing steps and to ensure repeatable and secure substrate handling by various automated handling equipment. However, the electrical performance of a semiconductor device can improve in various ways when the thickness of the semiconductor device has been reduced. Also, the package dimensions of the semiconductor package that includes a semiconductor device can be reduced if the semiconductor device is thinned.

Working with thinned semiconductor substrates and thinned semiconductor devices presents various challenges with respect to mechanical breakage of or damage to the substrates/devices. For example, where the semiconductor substrate is silicon and the thickness of the silicon substrate is less than 50 microns, it has been observed that during wirebonding to the gate pad of a particular semiconductor device, the underlying silicon beneath the pad can crack. The mechanical forces involved in the wirebonding process are sufficient to cause sufficient stress in the gate pad region to cause cracking of the silicon substrate. Cracking of the substrate can cause damage to the semiconductor device, the gate pad, or both. While the cracking can cause immediate destruction of the functionality of the semiconductor device, it can also not cause an immediate failure, but one that can take place over time during operation as a reliability failure. Since the cracking occurs under the pad, it may not be detectable with a visual inspection, which can further complicate detection of the defect.

Silicon and many other semiconductor substrates are crystalline structures which provides mechanical rigidity but also causes them to be brittle and inflexible compared to more ductile/elastically deformable materials like metals, polymers, passivation materials, or other carbon-based materials. The various semiconductor devices disclosed in this document replace the semiconductor substrate material below a gate pad with another material with greater elastic deformation properties than the semiconductor substrate material. In doing so, the material below the gate pad is able to elastically deform under the mechanical stresses of the wirebonding process and prevent formation of cracks in the semiconductor substrate material around the gate pad.

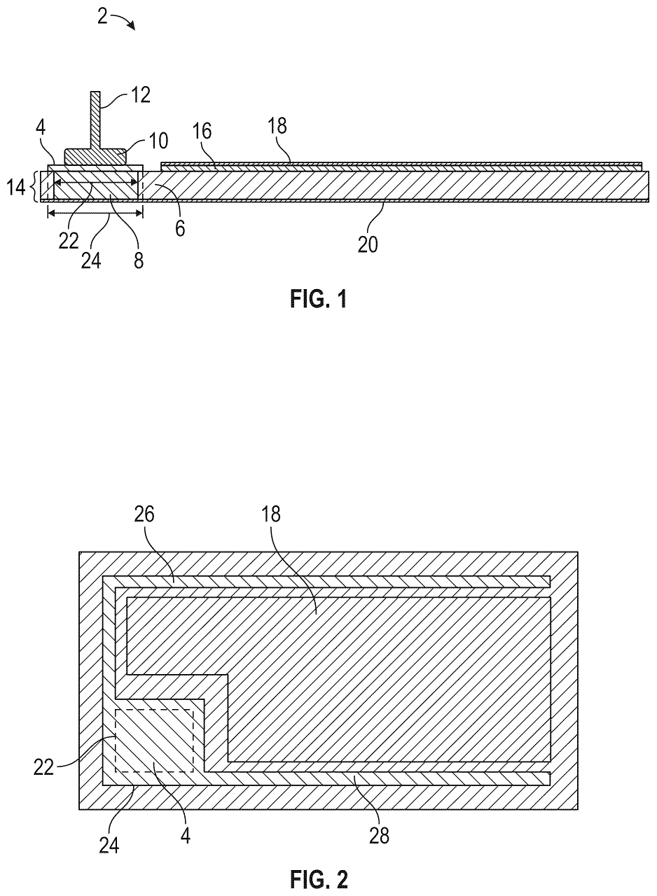

Referring to FIG. 1, an implementation of a semiconductor device 2 is illustrated. In this implementation, the semiconductor device is a power semiconductor device like an insulated gate bipolar transistors (IGBT), a diode, a rectifier, or a metal oxide field effect transistor (MOSFET), but the principles disclosed herein could be applied to other semiconductor devices that include a gate or other pad with a device structure compatible with inclusion of the structures disclosed herein. In the semiconductor device 2 illustrated, a gate pad 4 is included which is formed/coupled partially over semiconductor substrate 6 and electrically insulative material 8. The semiconductor substrate 6 may be any of a wide variety of semiconductor substrate types, including, by non-limiting example, silicon, silicon-on-insulator, silicon carbide, gallium arsenide, gallium nitride, sapphire, ruby, wide bandgap materials, or any other semiconductor material type.

As illustrated, a wirebond 10 that attaches bond wire 12 to the gate pad 4 is illustrated following completion of a wirebonding process to the gate pad 4. The thickness 14 of the semiconductor substrate 6 in this implementation is less than 50 microns. Additional pad(s) are also illustrated as being present in this semiconductor device 2 including one or more source pads 16 which, in this implementation, include a layer of a solderable top metal (STM) 18. This solderable top metal 18 may be formed of one or more layers of metals and/or metal alloys designed to assist with forming a strong mechanical and electrical connection to a substrate, leadframe, and/or circuit/mother board to which the semiconductor device 2 is attached. However, in various other implementations, a solder may not be used and the semiconductor device can be electrically/mechanical attached via sintering, wire bonding, or another die attach process/system. Here the use of a combination of wirebonding and soldering is illustrated to form electrical connections with the semiconductor device 2.

The semiconductor device 2 in FIG. 1 is also illustrated with a backmetal/backmetal layer 20 formed on the side of the device that was used for thinning. In various semiconductor device implementations, the backmetal 20 can act as a pad to form a drain connection for the device (as in the case of an IGBT), may act as a ground, or may simply work to facilitate physical die bonding of the backside of the die in the particular semiconductor package design in which the device is included. In various implementations, the backmetal may not be included. A wide variety of backmetal types formed of one or more layers of various metals/metal alloys may be employed with the various semiconductor devices disclosed herein.

The electrically insulative material 8 may be one of several different materials. In some semiconductor device implementations, the electrically insulative material 8 may be one of a mold compound, polymer material, resin, epoxy, any combination thereof, or another carbon-containing material that does not substantially conduct electricity. In some implementations the electrically insulative material 8 may include a filler or other material that may enhance the electrically insulative properties of the electrically insulative material. In other semiconductor device implementations, the electrically insulative material 8 may be a passivation material including, by non-limiting example, a nitride, an oxide, a polyimide, a benzocyclobutene, any combination thereof, or any other passivation material type. Various methods of forming the electrically insulative material are disclosed in this document. In the semiconductor device 2 illustrated in FIG. 1, the electrically insulative material is a mold compound.

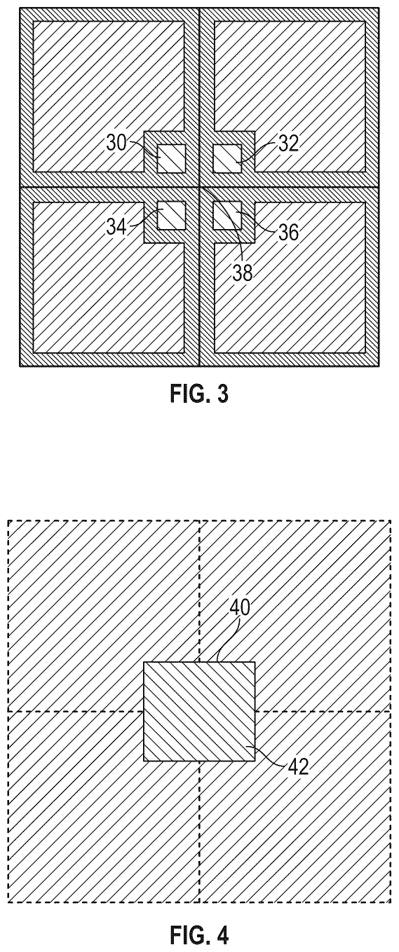

In the implementation illustrated in FIG. 1 and referring to FIG. 2, a perimeter 22 of the electrically insulative material 8 is within a perimeter 24 of the gate pad 4. Because the gate pad 4 is still in contact with the semiconductor substrate 6 adjacent to the perimeter 24, the gate pad 4 can still be electrically connected with portions of the semiconductor device. In this implementation, referring to FIG. 2, the gate pad 4 is connected with (in this implementation integrally formed) with gate runners 26, 28 that allow the gate pad 4 to interact electrically with the semiconductor device structures to allow the gate to perform its work managing flow of electrical current/charge in the semiconductor device. Source pad 16 is also illustrated adjacent to the gate runners 26, 28. The drain of the device illustrated in FIGS. 1 and 2 is the opposing side of the device and the backmetal layer 20 is used as the drain pad in this device. However, the implementation illustrated in FIG. 1 and FIG. 2 is intended merely as a non-limiting example to illustrate how the gate pad 4 can be coupled with additional structure(s) in the semiconductor device to allow it to function as desired while integrated with the electrically insulative material 8. Many gate pad configurations are possible depending on the type and design of the particular semiconductor device using the principles disclosed herein.

Where a mold compound is used as the electrically insulative material, the design of each semiconductor die can be carried out in such a way to allow alignment of the regions/openings in which the mold compound is applied with each other. Referring to FIG. 3, an implementation of four semiconductor die still connected through the underlying semiconductor substrate material prior to singulation is illustrated. Here four gate pads 30, 32, 34, 36 are illustrated in proximity to the same die street intersection 38. This arrangement can be accomplished during the design phase by mirroring one of the semiconductor die horizontally, vertically and both horizontally and vertically to create the alignment of the gate pads. FIG. 4 illustrates the view of the opposite largest planar side of the semiconductor die from FIG. 3 showing how the alignment of the gate pads 30, 32, 34, 36 allows a single region/opening 40 to be utilized into which mold compound 42 can be formed. The semiconductor die can then be singulated through the region of mold compound 42 into separate die. In this implementation, the perimeter of the resulting region of mold compound 42 associated with each individual semiconductor die will be larger on at least two sides than the corresponding gate pad 30, 32, 34, or 36. Thus the perimeter of the mold compound region will not be within the perimeter of the corresponding gate pad. In this implementation, a corner of each semiconductor die will have mold compound exposed along a portion of the thickness of the semiconductor die on each side. Using this alignment technique may simplify and improve the process of applying the mold compound during the fabrication process in various method implementations.

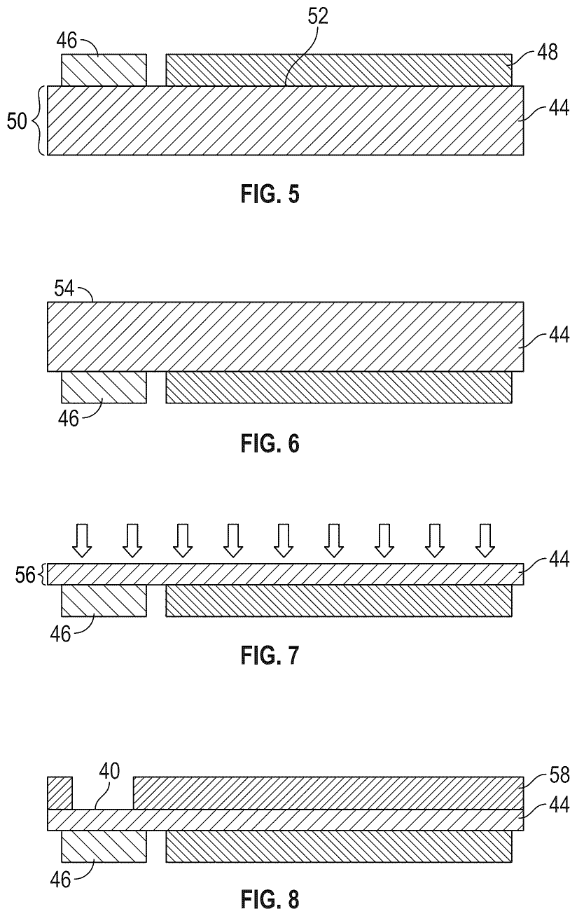

The various semiconductor device implementations disclosed herein may utilize various implementations of a method of forming a semiconductor device. Referring to FIG. 5, an implementation of a semiconductor substrate 44 is illustrated following formation of a gate pad 46 and a source pad 48 on a first largest planar surface 52. In some method implementations, the gate pad 46 and source pad 48 may be formed in the same processing step from the same metal layer(s). In other method implementations, the gate pad 46 and source pad 48 may be formed in different processing steps either from different metal layers or from the same metal layer. Here the thickness 50 of the semiconductor substrate is at its original or fabrication processing thickness. Following the formation of the gate pad 46, as illustrated in FIG. 6, the semiconductor substrate 44 may be flipped over to expose the second largest planar surface 54 (backside). In this orientation the semiconductor substrate 44 is prepared for a thinning operation directed from above the semiconductor substrate 44. However, in some method implementations, the semiconductor substrate 44 may be thinned from below the semiconductor substrate 44 so the semiconductor substrate 44 does not need to be flipped.

Referring to FIG. 7, the semiconductor substrate 44 is illustrated during a thinning operation that reduces the thickness 50 to a final thickness 56. The particular method used to thin the semiconductor substrate 44 may depend on the particular material of the semiconductor substrate. For example, for a silicon substrate, a grinding process may be utilized followed by a lapping process. For a silicon carbide substrate, a laser-induced damage process may be utilized followed by a separating process where a portion of the substrate is removed. A grinding process may then be used to further smooth the remaining surface of the substrate or the substrate may continue processing without lapping or grinding.

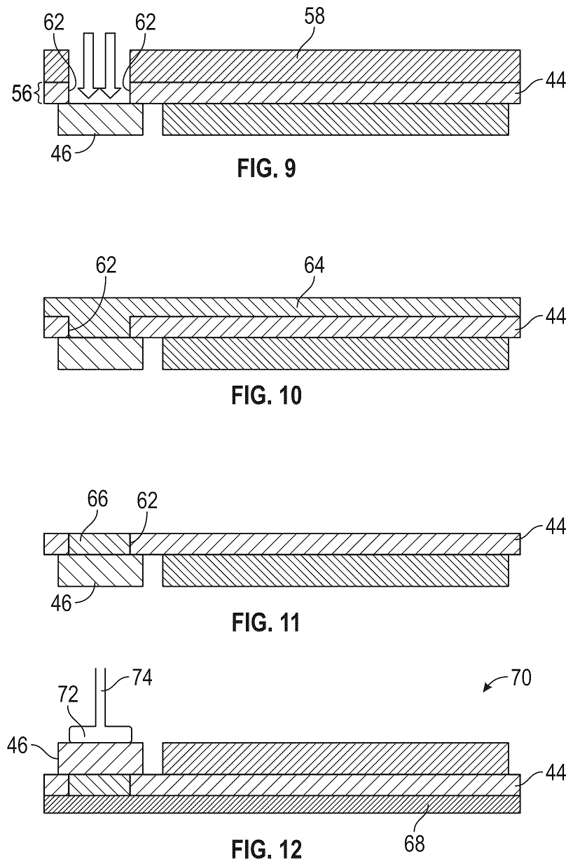

Referring to FIG. 8, following the thinning process, a patterned layer 58 is then formed on the semiconductor substrate 44. This patterned layer may be formed using a photolithography process to leave exposed portion(s) 60 of the semiconductor substrate 44 below the gate pad 46. In other implementations, stencil printing, screen printing, aligning, or other methods for forming an aligned patterned layer may be employed. FIG. 9 illustrates the semiconductor substrate 44 during etching process where the exposed portions 60 of the semiconductor substrate are being removed. In this implementation, the entire final thickness 56 of the exposed portions 60 has been removed through the etching process using the material of the gate pad 46 as a etch stop. Various etching processes can be utilized with chemistries that are consistent with the particular material of the semiconductor substrate 44. Dry etching or wet etching process may be utilized in various implementation. Following the completion of the etching process, the patterned layer 58 is removed through an ashing, etching, or solvent stripping process or other process consistent with the actual material of the patterned layer. The etching forms a gate pad opening 62 in the material/thickness of the semiconductor substrate 44. In this implementation, the perimeter of the gate pad opening 62 is within the perimeter of the gate pad, similar to the implementation illustrated in FIG. 2.

With the gate pad opening 62 in place, a mold compound is now applied over the semiconductor substrate to form mold compound layer 64. As illustrated, in this implementation, the mold compound extends over the entire surface of the semiconductor substrate 44 and into the gate pad opening 62. In some method implementations, where the locations of the gate pad openings are shared (like the semiconductor die implementations of FIG. 4), the mold compound 64 may not extend all the way across the entire surface but may be localized in the shared locations. A wide variety of methods of application may be utilized to form the mold compound including, by non-limiting example, transfer molding, injection molding, dispensing, squeegeeing, screen printing, or any other method capable of forming the layer of mold compound while ensuring it enters the gate pad opening 62. In some implementations, the process of applying the mold compound includes curing the mold compound to a desired curing stage. In other implementations, the process of applying the mold compound 64 may not include curing the mold compound and so curing may be done in a separate process. Curing of the mold compound 64 may take place using heat, ultraviolet light, any combination thereof, and/or the passage of a specific period of time in various method implementations.

Referring to FIG. 11, the semiconductor substrate 44 is illustrated following removal of the portion of the mold compound layer 64 that extended over the surface of the substrate. The removal process may take place using, by non-limiting example, a grinding process, an etching process, a polishing process, any combination thereof, or any other process compatible with removal of the particular type of mold compound used. The remaining mold compound 66 in the gate pad opening 62 forms the electrically insulative material adjacent to and directly coupled with the gate pad 46. Here, the gate pad 46 is still directly coupled adjacent to its perimeter to the material of the semiconductor substrate 44 as previously described. At this point, the semiconductor substrate 44 can be singulated to form various semiconductor die, or additional processing steps can be undertaken prior to singulation. For example, as illustrated in FIG. 12, a backmetal layer 68 may be applied to the semiconductor substrate 44 prior to singulation. FIG. 12 illustrates a singulated semiconductor die 70 following a wirebonding operation that formed wirebond 72 between gate pad 46 and bond wire 74. Because the mold compound is more elastically deformable during the wirebonding process than the material of the semiconductor substrate 44, the wirebond has been formed without creating cracks in the semiconductor substrate 44.

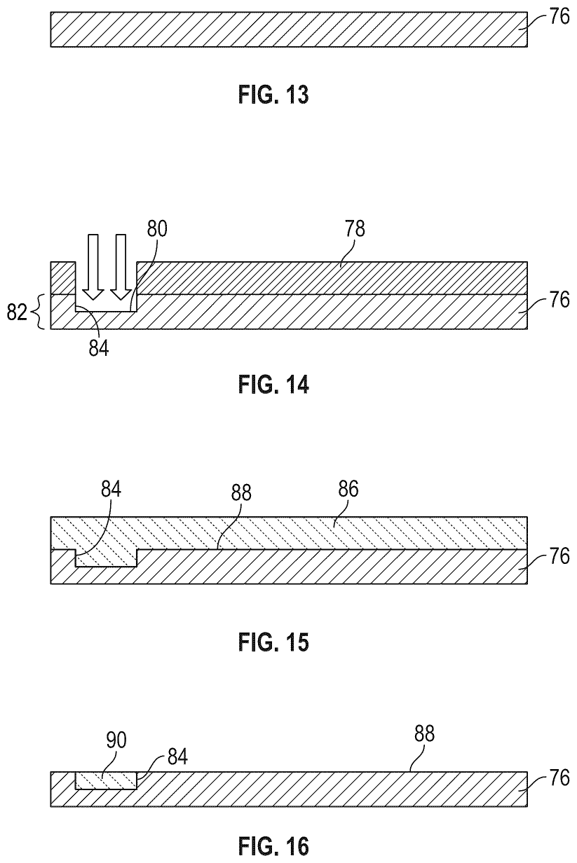

The foregoing method focuses on creating the electrically insulative material after the gate pad has been formed. In other method implementations, the electrically insulative material may be formed prior to formation of the gate pad. Referring to FIG. 13, an implementation of a semiconductor substrate 76 is illustrated following formation/fabrication of the device portions of semiconductor devices therein/thereon but before formation of any pad structures. FIG. 14 illustrates the semiconductor substrate 76 following formation of a patterned layer 78 thereon that leaves portions 80 of the semiconductor substrate 76 exposed. An etching process, as illustrated in FIG. 14, is being used to etch into the thickness 82 of the semiconductor substrate 76 a predetermined distance. As there may be no etch stop layer available to use during this etching process, a timed etching process may be used to ensure that the gate pad opening 84 being formed reaches a desired depth into the thickness 82 and a desired size.

Referring to FIG. 15, following the etching process, a layer of passivation material 86 is formed over a first largest planar surface 88 of the semiconductor substrate 76 and into the gate pad opening 84. The passivation material 86 may be any such material type disclosed in this document and may be formed using any process consistent with the type of material, including, by non-limiting example, chemical vapor deposition, spin coating, sputtering, any combination thereof, or any other process designed to fill the gate pad opening 84. In some implementations like the one illustrated in FIG. 4, the application/deposition process for the passivation material 86 may occur through a patterned layer while a patterned layer is applied to the semiconductor substrate 76. In these implementations, the passivation material 86 may be limited to the gate pad opening(s) and so may not extend substantially across the largest planar surface 88 of the semiconductor substrate 76. In some implementations, this means that no subsequent thinning/planarization of the passivation material may be needed.

FIG. 16 illustrates the semiconductor substrate 76 following removal of the layer of passivation material 86 from the largest planar surface 88 thus leaving passivation material 90 in the gate pad opening 84 as electrically insulative material. The removal process for the layer of passivation material 86 may be any consistent with the type of material used. Where the material is a nitride or oxide, a chemical mechanical planarization process may be utilized. There the material is a polymer or other carbon-containing material, an etching or grinding process may be used. At this point, with the largest planar surface 88 exposed, the semiconductor substrate 76 is ready for additional processing steps to form the final layer of interconnects to the various semiconductor devices included in the substrate.

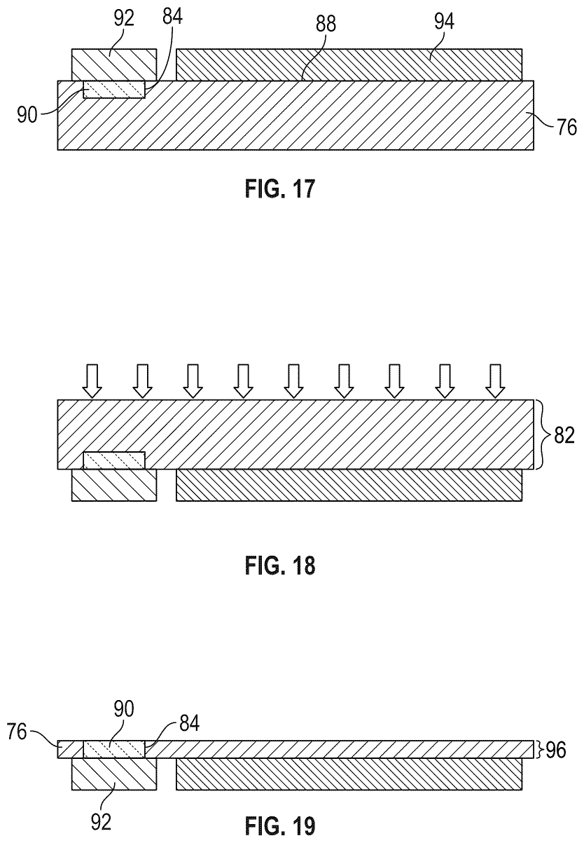

Referring to FIG. 17, the semiconductor substrate 76 is illustrated following formation of gate pad 92 and source pad 94 on the largest planar surface 88. As previously described, the gate pad 92 and source pad 94 may be formed in the same process from the same metal layer or may be formed separately from the same layer or separately from different layers of material, depending on the particular method implementation being used. Here, the gate pad 92 is formed over the passivation material 90 in such a way that the perimeter of the gate pad opening 84 that contains the passivation material 90 is within a perimeter of the gate pad 92. In other implementations, this may not be the case, as in the implementation illustrated in FIG. 4 where the perimeter of the gate pad opening 84 would extend all the way to one corner of each semiconductor die of the semiconductor substrate 76. Because the material of the passivation material 90 has been selected to facilitate adhesion of the metal of the gate pad 92, the gate pad 92 can be successfully formed on the material of the passivation material 90 and on the material of the semiconductor substrate 76. Various lithographic processes in combination with metal deposition and etching may be used to form the gate pad 92 and source pad 94 in different method implementations.

In this method implementation, following formation of the pads, the thickness of the semiconductor substrate 76 is ready for thinning. FIG. 18 illustrates the semiconductor substrate 76 in a flipped orientation from FIG. 17 during a thinning process which may be any disclosed in this document consistent with the particular material of the semiconductor substrate. Here the thinning is used to reduce the thickness 82 to a final thickness 96 illustrated in FIG. 19. In FIG. 19, the final thickness 96 is illustrated as being the same as the remaining thickness of the passivation material 90 in the gate pad opening 84 following the thinning process. In other implementations, however, the final thickness 96 may be greater than the remaining thickness of the passivation material 90, leaving a portion of the material of the semiconductor substrate 76 extending underneath/adjacent the side of the passivation material opposite the side that contacts the gate pad 92. In such implementations with a remaining portion of semiconductor substrate underneath the passivation material, the presence and thickness of the remaining portion may be calculated after testing to verify that the passivation material 90 is sufficiently elastically protective to prevent formation of cracks in the remaining portion of the semiconductor substrate. The testing could also show in some implementations that the presence of the passivation material 90 may ensure that any cracking in the remaining portion of the semiconductor substrate 76 adjacent to the passivation material is isolated and does not spread further into the semiconductor substrate.

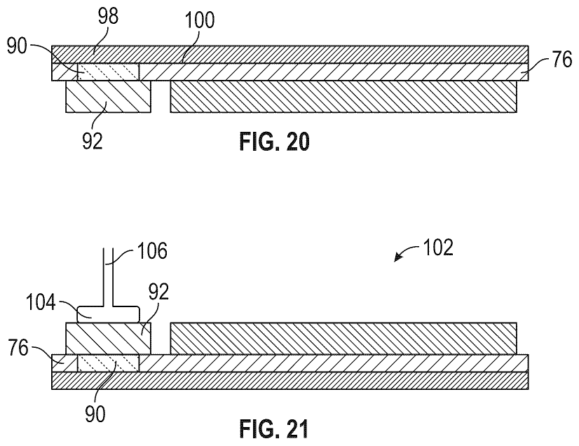

The semiconductor substrate 76 illustrated in FIG. 19 could now be singulated into individual semiconductor die without further processing in various implementations. However, additional processing operations could be carried out including, referring to FIG. 20, the formation of a backmetal (backmetal layer) thereon. FIG. 20 illustrates the semiconductor substrate 76 following formation of backmetal layer 98 over a second largest planar surface 100 of the semiconductor substrate 76. Any of the backmetal types disclosed in this document could be utilized here and may be applied using any of the methods provided the backmetal layer materials will adhere to the particular material of the passivation material 90.

The semiconductor substrate 76 is now ready for singulation into individual semiconductor die which are then ready for additional processing into a semiconductor package or directly application to a circuit/motherboard. FIG. 21 illustrates a semiconductor die 102 following a wirebonding process that formed wirebond 104 on gate pad 92 to attach bond wire 106 thereto. As illustrated, in this implementation the passivation material 90 provided sufficient elastic support to prevent formation of cracks in the adjacent material of the semiconductor substrate 76 during the wirebonding process.

While the method and structure examples provided in this document are directed to gate pads of various semiconductor devices, the principles could also be adapted for other pad types, like source, drain, signal, or supporting pad types. Where other pad types are utilized, the principles may be modified to allow for sufficient electrical contact(s) with the pad. For example, the perimeter of the opening used with other types of pads may not fully enclose the perimeter of the pad, allowing a portion of the pad to electrically contact the semiconductor substrate material. This contact between the pad and the semiconductor substrate material may be sufficient to allow the pad to operate to carry the desired electrical signal(s) to permit the semiconductor device to operate normally or as desired.

The various semiconductor die that include the semiconductor devices disclosed in this document may subsequently be included in a semiconductor package. Various semiconductor packages include one or more substrates as a component of the packages. The substrates can be formed using various materials and may be, by non-limiting example, direct bonded copper (DBC) substrates, active metal brazed (AMB) substrates, aluminum nitride substrates, alumina substrates, insulated metal substrates (IMS), leadframes, any combination thereof, or any other substrate type.

In various package implementations, the substrates may include one or more traces in one or more layers thereon. In various implementations, the substrates may include a combination of one or more electrically conductive layers with one or more electrically insulative layers. In some substrate implementations, a top layer of the substrate is exposed after package formation; in others, a mold compound or potting compound may cover the top layer. For packages where a mold compound is employed with the substrate, the mold compound may cover various surfaces of the substrate to help form electrically insulated areas. In various package implementations, various electrical connectors may be employed to form electrical connections between to the substrate and the one or more semiconductor die included therein including, by non-limiting example, wire bonds, clips, leads, pins, or any other electrical connector type.

In places where the description above refers to particular implementations of semiconductor devices and implementing components, sub-components, methods and sub-methods, it should be readily apparent that a number of modifications may be made without departing from the spirit thereof and that these implementations, implementing components, sub-components, methods and sub-methods may be applied to other semiconductor devices.

What is claimed is:

1. A semiconductor device comprising:
a semiconductor substrate comprising a thickness;
a gate pad coupled to the semiconductor substrate; and
an electrically insulative material in the thickness of the semiconductor substrate directly coupled to the gate pad.

2. The device of claim 1, wherein the electrically insulative material extends entirely across the thickness of the semiconductor substrate.

3. The device of claim 1, wherein the semiconductor substrate and the electrically insulative material are covered with a backmetal material.

4. The device of claim 1, further comprising one or more gate runners electrically coupled with the gate pad.

5. The device of claim 1, further comprising a bond wire directly coupled to the gate pad.

6. The device of claim 1, wherein a perimeter of the electrically insulative material is within a perimeter of the gate pad.

7. The device of claim 1, wherein the thickness of the semiconductor substrate is less than 50 microns thick.

8. The device of claim 1, wherein the electrically insulative material is a mold compound.

9. The device of claim 1, wherein the electrically insulative material is a passivation material.

10. A method of making a semiconductor device, the method comprising:
providing a semiconductor substrate comprising a thickness;
forming a gate pad on a surface of the semiconductor substrate;
thinning the thickness of the semiconductor substrate to a final thickness;
adjacent to the gate pad, etching the semiconductor substrate through the final thickness to form a gate pad opening; and
applying a mold compound into the gate pad opening.

11. The method of claim 10, further comprising forming a patterned layer on the semiconductor substrate prior to etching the semiconductor substrate.

12. The method of claim 10, further comprising removing the mold compound from a largest planar surface of the semiconductor substrate after applying.

13. The method of claim 10, further comprising forming a backmetal layer over a largest planar surface of the semiconductor substrate and over the mold compound.

14. The method of claim 10, further comprising wirebonding a bond wire to the gate pad.

15. A method of making a semiconductor device, the method comprising:
providing a semiconductor substrate comprising a thickness;
forming a patterned layer on a first largest planar surface of the semiconductor substrate;
etching the semiconductor substrate into the thickness to form a gate pad opening;
forming a layer of passivation material on the first largest planar surface and into the gate pad opening;
removing the layer of passivation material from the first largest planar surface;
forming a gate pad over the gate pad opening; and
thinning the thickness of the semiconductor substrate to a final thickness.

16. The method of claim 15, further comprising removing the patterned layer on the semiconductor substrate after etching the semiconductor substrate.

17. The method of claim 15, further comprising forming a backmetal layer over a second largest planar surface of the semiconductor substrate.

18. The method of claim 15, further comprising wirebonding a bond wire to the gate pad.

19. The method of claim 15, wherein the gate pad opening extends only partially into the final thickness.

20. The method of claim 15, wherein a perimeter of the gate pad opening is within a perimeter of the gate pad.
